(19) United States
(12) Patent Application Publication
(10) Pub. No.: US 2024/0250072 A1
(43) Pub. Date: Jul. 25, 2024

(54) SEMICONDUCTOR PACKAGE

(71) Applicant: SAMSUNG ELECTRONICS CO., LTD., Suwon-si (KR)

(72) Inventor: Youngdeuk KIM, Suwon-si (KR)

(21) Appl. No.: 18/492,170

(22) Filed: Oct. 23, 2023

(30) Foreign Application Priority Data
Jan. 20, 2023 (KR) 10-2023-0008886

(51) Int. Cl. H01L 25/065; H01L 23/00; H01L 23/31; H01L 23/48; H01L 23/498

(52) U.S. Cl. CPC H01L 25/0657; H01L 23/3107; H01L 23/481; H01L 23/49894; H01L 24/16; H01L 24/32; H01L 24/73; H01L 25/0652; H01L 2224/16148; H01L 2224/16227; H01L 2224/16238; H01L 2224/32145; H01L 2224/73204; H01L 2225/06513; H01L 2225/06544; H01L 2924/1431; H01L 2924/1436; H01L 2924/1437; H01L 2924/1438

(57) ABSTRACT

A semiconductor package includes a first semiconductor chip including a substrate having a front surface and an opposite rear surface, a rear protective layer on the rear surface, a plurality of first and second rear through-vias penetrating through the rear protective layer and extending into the substrate, a plurality of front through-vias extending from the front surface and connected to the first rear through-vias, and a plurality of rear pads on the rear protective layer and connected to the plurality of first and second rear through-vias. A second semiconductor chip is on the first semiconductor chip, and includes a plurality of front pads electrically connected to the plurality of rear pads by respective bump structures. Each of the plurality of rear through-vias has a width greater than a width of each of the plurality of front through-vias.

### CROSS-REFERENCE TO RELATED APPLICATION(S)

This application claims benefit of priority to Korean Patent Application No. 10-2023-0008886, filed on Jan. 20, 2023, in the Korean Intellectual Property Office, the disclosure of which is incorporated herein by reference in its entirety.

### BACKGROUND

The present inventive concept relates to semiconductor packages.

In accordance with lightweightedness and high performance of electronic devices, development of miniaturization and high performance has also been required in the field of semiconductor packages. In order to implement miniaturization, lightweightedness, high performance, and high reliability of semiconductor packages, research and development concerning semiconductor packages in which semiconductor chips are vertically stacked have been continuously conducted.

### SUMMARY

An aspect of the present inventive concept is to provide semiconductor packages having improved heat dissipation characteristics.

According to an aspect of the present inventive concept, provided is a semiconductor package, the semiconductor package including: a first semiconductor chip including a substrate having a front surface and an opposite rear surface, a rear protective layer on the rear surface of the substrate, a plurality of first rear through-vias penetrating through the rear protective layer and extending into the substrate, a plurality of second rear through-vias penetrating through the rear protective layer and extending into the substrate, a plurality of front through-vias extending from the front surface of the substrate and connected to the plurality of first rear through-vias, and a plurality of rear pads on the rear protective layer and connected to the plurality of first and second rear through-vias; a second semiconductor chip on the first semiconductor chip, and including a plurality of front pads electrically connected to the plurality of rear pads; a plurality of bump structures between the plurality of rear pads of the first semiconductor chip and the plurality of front pads of the second semiconductor chip; and an adhesive layer surrounding the plurality of bump structures between the first semiconductor chip and the second semiconductor chip, wherein each of the plurality of first and second rear through-vias has a width greater than a width of each of the plurality of front through-vias.

According to an aspect of the present inventive concept, provided is a semiconductor package, the semiconductor package including: a plurality of semiconductor chips stacked in a first direction; a plurality of bump structures between and electrically connecting adjacent ones of the plurality of semiconductor chips; and at least one adhesive layer surrounding the plurality of bump structures, wherein at least one of the plurality of semiconductor chips includes: a substrate having a front surface and an opposite rear surface; a rear protective layer on the rear surface of the substrate; a plurality of rear pads on the rear protective layer; a plurality of rear through-vias penetrating through the rear protective layer and connected to the plurality of rear pads; a front circuit layer on the front surface of the substrate; a plurality of front pads on the front circuit layer, and a plurality of front through-vias extending from the front surface of the substrate to at least a portion of the plurality of rear through-vias, and electrically connected to at least a portion of the plurality of front pads.

According to an aspect of the present inventive concept, provided is a semiconductor package, the semiconductor package including: a first semiconductor chip including a substrate having a front surface and an opposite rear surface, a rear protective layer on the rear surface of the substrate, a plurality of rear through-vias penetrating through the rear protective layer and extending into the substrate, a plurality of front through-vias extending from the front surface of the substrate and connected to the plurality of rear through-vias, and a plurality of rear pads on the rear protective layer and connected to the plurality of rear through-vias; a second semiconductor chip on the first semiconductor chip, and including a plurality of front pads electrically connected to the plurality of rear pads; a plurality of bump structures between the plurality of rear pads of the first semiconductor chip and the plurality of front pads of the second semiconductor chip; an adhesive layer surrounding the plurality of bump structures between the first semiconductor chip and the second semiconductor chip, wherein the plurality of rear through-vias include a plurality of first rear through-vias electrically connected to the plurality of front through-vias and a plurality of second rear through-vias electrically insulated from the plurality of front through-vias.

### BRIEF DESCRIPTION OF DRAWINGS

The above and other aspects, features, and advantages of the present disclosure will be more clearly understood from the following detailed description, taken in conjunction with the accompanying drawings.

FIG. 1A is a cross-sectional view illustrating a semiconductor package according to an example embodiment, FIG. 1B is a plan view illustrating a first semiconductor chip of FIG. 1A, and FIG. 1C is a partially enlarged view of a region ‘A’ of FIG. 1A.

FIGS. 2A to 2C are cross-sectional views illustrating one region of a semiconductor package according to example embodiments.

FIGS. 3A to 3I are cross-sectional views of major processes of a method of manufacturing a semiconductor package according to an example embodiment of the present inventive concept.

FIG. 4 is a cross-sectional view illustrating a semiconductor package according to an example embodiment of the present inventive concept.

FIG. 5 is a cross-sectional view illustrating a semiconductor package according to an example embodiment of the present inventive concept.

### DETAILED DESCRIPTION

Hereinafter, with reference to the accompanying drawings, preferred example embodiments of the present inventive concept will be described as follows. Unless otherwise specified, in this specification, terms such as ‘upper portion,’ ‘upper surface,’ ‘lower portion,’ ‘lower surface,’ ‘side surface,’ and the like, are based on the drawings, and in fact, it may vary depending on a direction in which the components are disposed.

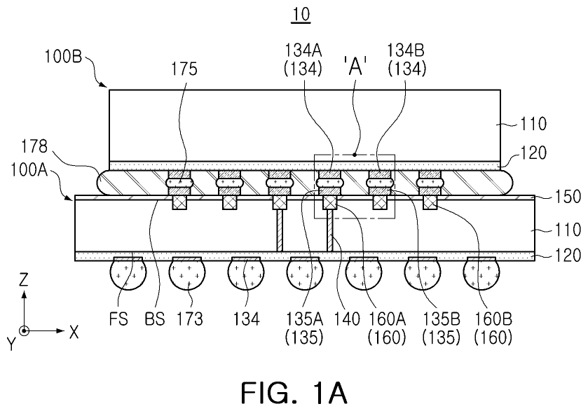

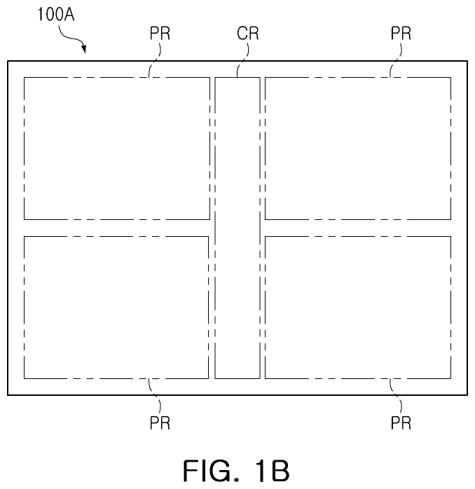

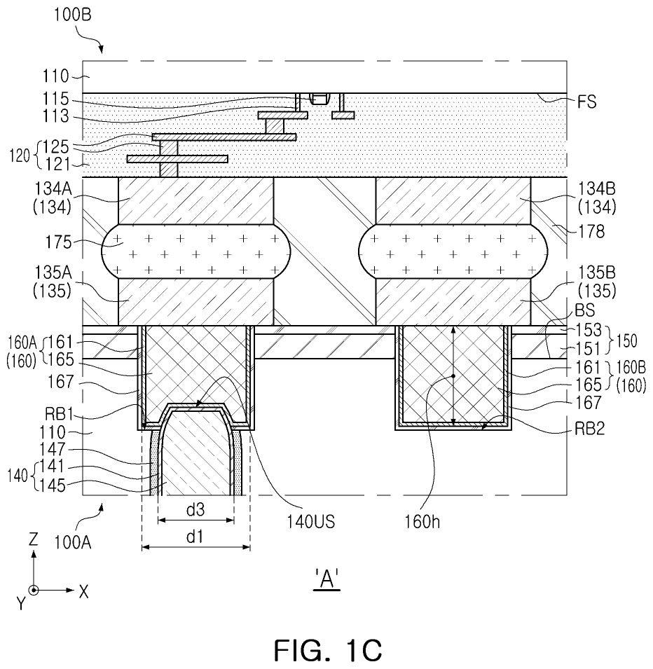

FIG. 1A is a cross-sectional view of a semiconductor package 10 according to an example embodiment, FIG. 1B is a plan view of a first semiconductor chip 100A of FIG. 1A, and FIG. 1C is a partially enlarged view illustrating a region ‘A’ of FIG. 1A.

Referring to FIGS. 1A to 1C, a semiconductor package 10 according to an example embodiment may include a plurality of semiconductor chips 100A and 100B stacked in a vertical direction (Z-direction), bump structures 175, and an adhesive layer 178. In FIG. 1A, a width of the first semiconductor chip 100A in a horizontal direction (e.g., X-direction) is illustrated to be greater than a width of the second semiconductor chip 100B, but according to an example embodiment, the width of the first semiconductor chip 100A in the horizontal direction (e.g., X-direction) may be substantially equal to or smaller than a width of the second semiconductor chip 100B. In the present inventive concept, by introducing a plurality of rear through-vias 160 penetrating through the rear protective layer 150 of at least one of semiconductor chips (e.g., the first semiconductor chip 100A), it is possible to secure a heat dissipation path in a vertical direction and improve heat dissipation characteristics of the semiconductor package 10.

Hereinafter, components of the semiconductor package 10 will be described in detail.

The plurality of semiconductor chips 100A and 100B may include, for example, a first semiconductor chip 100A and a second semiconductor chip 100B. According to example embodiments, the first semiconductor chip 100A and the second semiconductor chip 100B may be chiplets constituting a multi-chip module (MCM). The number of second semiconductor chips 100B vertically or horizontally stacked on the first semiconductor chip 100A may be two or more. The first semiconductor chip 100A may include, for example, a logic chip such as a central processor (CPU), a graphics processor (GPU), a field programmable gate array (FPGA), an application processor (AP), a digital signal processor (DSP), a cryptographic processor, a microprocessor, a microcontroller, an analog-to-digital converter, an application specific integrated circuits (ASIC), and the like, and the second semiconductor chip 100B may include a volatile memory device such as dynamic RAM (DRAM) and static RAM (SRAM), a non-volatile memory device such as phase change RAM (PRAM), magnetic RAM (MRAM), resistive RAM (RRAM), and flash memory device.

The plurality of semiconductor chips 100A and 100B may include a substrate 110, a front circuit layer 120, a plurality of front pads 134, a plurality of rear pads 135, a plurality of front through-vias 140, a rear protective layer 150 and/or a plurality of rear through-vias 160. In an example embodiment, the plurality of semiconductor chips 100A and 100B may include a first semiconductor chip 100A and a second semiconductor chip 100B disposed on the first semiconductor chip 100A. The first semiconductor chip 100A may include a substrate 110, a front circuit layer 120, a plurality of front pads 134, a plurality of rear pads 135, a plurality of front through-vias 140, a rear protective layer 150, and a plurality of rear through-vias 160. The second semiconductor chip 100B may include a substrate 110, a front circuit layer 120, and a plurality of front pads 134.

The substrate 110 may be a semiconductor wafer substrate having a front surface FS and a rear surface BS opposing each other. For example, the substrate 110 may include a semiconductor element such as silicon (Si) or germanium (Ge), or a compound semiconductor such as silicon carbide (SiC), gallium arsenide (GaAs), indium arsenide (InAs), and indium phosphide (InP). The front surface FS may be an active surface having an active region doped with impurities, and the rear surface BS may be an inactive surface located opposite to the front surface FS.

The front circuit layer 120 may be disposed on the front surface FS of the substrate 110, and may include an interconnection structure 125 connected to the active region and an interlayer insulating layer 121 surrounding the interconnection structure 125. The interlayer insulating layer 121 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. At least a portion of the interlayer insulating layer 121 surrounding the interconnection structure 125 may be formed of a low-dielectric layer. The interlayer insulating layer 121 may be formed using a chemical vapor deposition (CVD) process, a flowable-CVD process, or a spin coating process. The interconnection structure 125 may be formed in a multilayer structure including interconnection patterns and vias including, for example, aluminum (Al), gold (Au), cobalt (Co), copper (Cu), nickel (Ni), lead (Pb), tantalum (Ta), tellurium (Te), titanium (Ti), tungsten (W), or a combination thereof. A barrier film (not shown) including titanium (Ti), titanium nitride (TiN), tantalum (Ta), or tantalum nitride (TaN) may be disposed between the interconnection structure 125 and the interlayer insulating layer 121. Individual devices 115 constituting an integrated circuit may be disposed on the front surface FS of the substrate 110. In this case, the interconnection structure 125 may be electrically connected to the individual devices 115 through an interconnection portion 113 (e.g., contact plugs). The individual devices 115 may include a field effect transistor (FET) such as planar FET or FinFET, memory devices such as flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), resistive random access memory (RRAM), logic devices such as AND, OR, NOT, and various active devices and/or passive devices such as system large scale integration (LSI), a CMOS imaging sensor (CIS), and a microelectromechanical system (MEMS).

The plurality of front pads 134 may be disposed on the front circuit layer 120, and be electrically connected to the interconnection structure 125. The plurality of rear pads 135 may be disposed on the rear protective layer 150, and may be connected to the plurality of rear through-vias 160. The plurality of rear pads 135 and the plurality of front pads 134, adjacent to each other in a vertical direction (Z-direction) may be electrically connected to each other by bump structures 175. The plurality of front pads 134 and the plurality of rear pads 135 may be formed of a conductive material, for example, aluminum (Al), gold (Au), cobalt (Co), copper (Cu), nickel (Ni), may include lead (Pb), tantalum (Ta), tellurium (Te), titanium (Ti), tungsten (W), or a combination thereof. A barrier film (not shown) including titanium (Ti), titanium nitride (TiN), tantalum (Ta), or tantalum nitride (TaN) may be disposed on at least one surface of the plurality of front pads 134 and the plurality of rear pads 135. Connection bumps 173 may be disposed below a lowermost semiconductor chip (e.g., a first semiconductor chip 100A) among the plurality of semiconductor chips 100A and 100B. The connection bumps 173 may be disposed on the front pads 134 of the first semiconductor chip 100A. The connection bumps 173 may be, for example, conductive bump structures such as solder balls, copper (Cu) posts, or the like.

The plurality of front through-vias 140 may extend from the front surface FS of the substrate 110 to at least some of the plurality of rear through-vias (e.g., first rear through-vias 160A), and may be electrically connected to at least some of the plurality of front pads 134. The plurality of front through-vias 140 may be connected to the interconnection structure 125 of the front circuit layer 120, for example, a signal interconnection, a power interconnection, and a ground interconnection. The plurality of front through-vias 140 may further protrude than the first recess surface RB1 of the substrate 110 surrounding lower portions of the first rear through-vias 160A. For example, the lower surfaces of the first rear through-vias 160A may include recessed portions in contact with the upper surfaces 140US of the plurality of front through-vias 140. Accordingly, at least a portion of each of the plurality of front through-vias 140 may directly be in contact with the first rear through-vias 160A. The plurality of front through-vias 140 may include a via plug 145 and a surface barrier layer 141 surrounding a side surface of the via plug 145. The via plug 145 may include, for example, tungsten (W), titanium (Ti), aluminum (Al), or copper (Cu), and may be formed by a plating process, a PVD process, or a CVD process. The surface barrier layer 141 may include titanium (Ti), titanium nitride (TiN), tantalum (Ta), or tantalum nitride (TaN), and may be formed by a plating process, a PVD process, or a CVD process.

In addition, a side insulating film 147 extending in some side surfaces of the plurality of front through-vias 140 surrounded by the substrate 110 may be formed around the plurality of front through-vias 140. The side insulating film 147 may electrically isolate the via plug 145 from the substrate 110. The side insulating film 147 may include an insulating material (e.g., HARP (High Aspect Ratio Process) oxide) such as silicon oxide, silicon nitride, or silicon oxynitride, and may be formed by a PVD process or a CVD process.

The rear protective layer 150 may be disposed on a rear surface BS of the substrate 110, and may include an insulating material. The rear protective layer 150 may include, for example, silicon oxide, silicon nitride, silicon carbide, silicon oxynitride, silicon carbonitride, and the like. According to an example embodiment, the rear protective layer 150 may include a plurality of protective layers. For example, the rear protective layer 150 may include a first protective layer 151 and a second protective layer 153 including different materials. The first protective layer 151 may include silicon oxide, and the second protective layer 153 may include silicon nitride, but an example embodiment thereof is not limited thereto. According to an example embodiment, the rear protective layer 150 may be a single layer formed of silicon oxide. The rear protective layer 150 may protect a rear surface BS of the substrate 100, and may electrically insulate between the rear pads 135 and the substrate 110. However, heat dissipation characteristics of the semiconductor package may be deteriorated due to low thermal conductivity of the rear surface protective layer 150. According to example embodiments of the present inventive concept, the rear through-vias 160 may provide a heat dissipation path which is vertically connected by penetrating through the rear protective layer 150.

The plurality of rear through-vias 160 may penetrate through the rear protective layer 150, and extend into the substrate 110. The plurality of rear through-vias 160 may be electrically connected to the plurality of rear surface pads 135. The plurality of rear through-vias 160 may include a second via plug 165 and a second surface barrier layer 161 surrounding a side surface of the second via plug 165. The second via plug 165 may include, for example, tungsten (W), titanium (Ti), aluminum (Al), or copper (Cu), and may be formed by a plating process, a PVD process, or a CVD process. The second surface barrier layer 161 may include titanium (Ti), titanium nitride (TiN), tantalum (Ta), or tantalum nitride (TaN), and may be formed by a plating process, a PVD process, or a CVD process.

In addition, the plurality of rear through-vias 160 may be electrically insulated from the substrate 110 by a barrier insulating layer 167. The barrier insulating layer 167 may extend between the substrate 110 and the plurality of rear through-vias 160. The barrier insulating layer 167 may electrically isolate the second via plug 165 from the substrate 110. The barrier insulating layer 167 may include at least one of silicon oxide and silicon nitride. The barrier insulating layer 167 may be formed by a PVD process or a CVD process.

The plurality of rear through-vias 160 may include first rear through-vias 160A and second rear through-vias 160B. The first rear through-vias 160A may be electrically connected to the first rear pads 135A, the plurality of front through-vias 140, and the first front pads 134A. The second rear through-vias 160B may be electrically connected to the second rear surface pads 135B and the second front surface pads 134B, and may be electrically insulated from the plurality of front through-vias 140. The first rear through-vias 160A may be disposed in a center region CR of the semiconductor chip (e.g., the first semiconductor chip 100A), and the second rear through-vias 160B may be disposed in a peripheral region PR of the semiconductor chip (e.g., the first semiconductor chip 100A) (see FIG. 1B). The center region CR is a region crossing a center of the semiconductor chip on a plane, and may be defined as a region in which the plurality of front through-vias 140 are arranged. The peripheral region PR may be disposed around the center region CR. The second rear through-vias 160B disposed in the peripheral region PR may be electrically insulated from the plurality of front through-vias 140. According to the example embodiment, the plurality of front through-vias 140 may further include dummy through-vias (not shown) disposed in the peripheral region PR. In this case, the second rear through-vias 160B may be electrically connected to the dummy through-vias (not shown).

The plurality of rear through-vias 160 may have a width greater than the width d3 of the plurality of front through-vias 140 in a horizontal direction (e.g., X-direction), as illustrated in FIG. 1C. Accordingly, the plurality of rear through-vias 160 may more effectively secure a heat dissipation path penetrating through the rear protective layer 150. For example, a width d1 of the first rear through-vias 160A may be greater than the width d3 of the plurality of front vias 140. For example, the width (e.g., d1) of the plurality of rear through-vias 160 may be in a range of about 5 μm to about 20 μm, of about 5 μm to about 15 μm, and of about 5 μm to about 10 μm, and the width d3 of the plurality of front through-vias 140 may be in a range of about 2 μm to about 8 μm, about 3 μm to about 6 m, and about 4 μm to about 5 μm, but an example embodiment thereof is not limited thereto.

The plurality of rear through-vias 160 may have a height 160h, smaller than that of the plurality of front through-vias 140. For example, the height 160h of the plurality of rear through-vias 160 may be in a range of about 2 μm to about 10 μm, about 3 μm to about 9 μm, and about 4 μm to about 8 μm, but an example embodiment thereof is not limited thereto.

The bump structures 175 may be disposed between the plurality of semiconductor chips 100A and 100B. The bump structures 175 may electrically connect the plurality of rear surface pads 135 and the plurality of front pads 134, adjacent to each other in a vertical direction (i.e., the Z direction). The bump structures 175 may include, for example, solder, but may include both pillars and solder according to example embodiments. The pillar has a cylindrical column shape or a polygonal column shape such as a square column or an octagonal column, and may include, for example, nickel (Ni), copper (Cu), palladium (Pd), platinum (Pt), gold (Au), or a combination thereof. The solder has a spherical or ball shape, and may include, for example, tin (Sn), indium (In), bismuth (Bi), antimony (Sb), copper (Cu), silver (Ag), zinc (Zn), Lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and the like.

The adhesive layer 178 may surround the bump structures 175 between the plurality of semiconductor chips 100A and 100B. The adhesive layer 178 may fix the plurality of semiconductor chips 100A and 100B, which are vertically stacked. The adhesive layer 178 may be a non-conductive film (NCF) or a molded underfill (MUF), but an example embodiment thereof is not limited thereto. The adhesive layer 178 may include at least one of an epoxy resin, silica (SiO₂), and an acrylic copolymer, or a combination thereof.

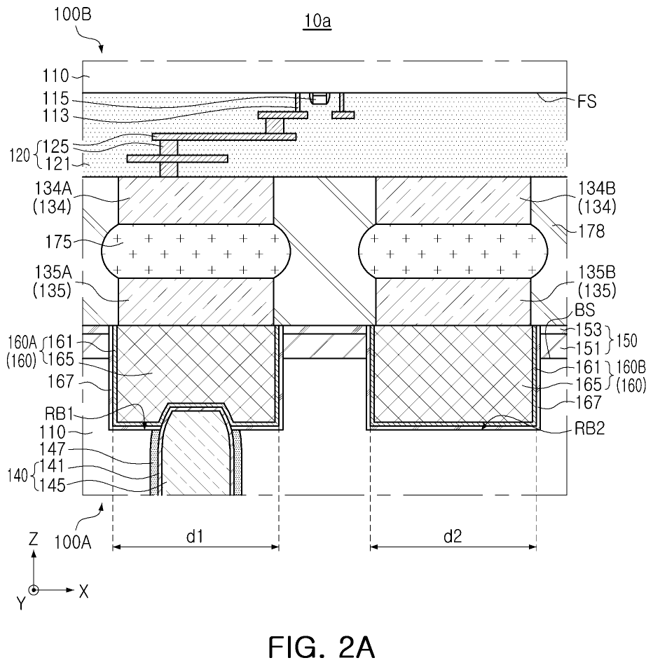

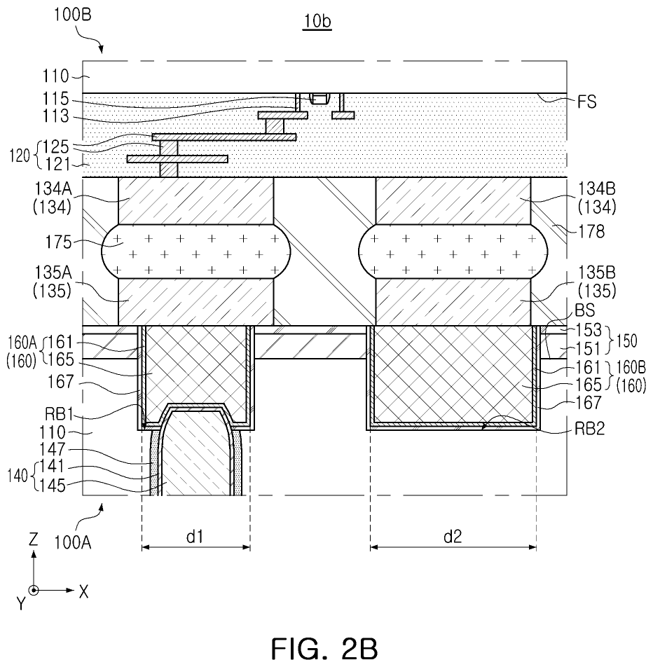

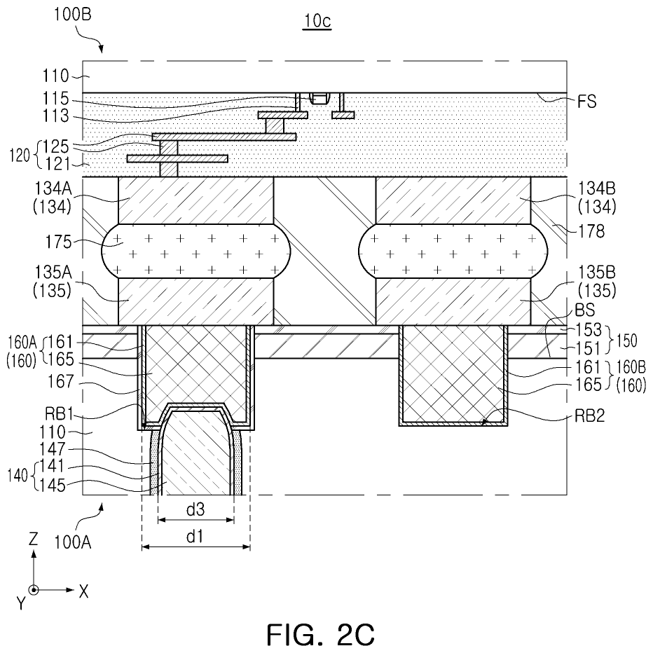

FIGS. 2A to 2C are cross-sectional views illustrating one region of semiconductor packages 10a, 10b, and 10c according to example embodiments. FIGS. 2A to 2C show a region corresponding to FIG. 1C of semiconductor packages 10a, 10b and 10c.

Referring to FIG. 2A, in the semiconductor package 10a according to an example embodiment, a plurality of rear through-vias 160 may have a width greater than that of the plurality of rear pads 135. For example, a width d1 of the first rear through-vias 160A and a width d2 of the second rear through-vias 160B may be greater than a width of the first rear pads 135A and a width of the second rear pads 135B, respectively. According to an example embodiment, the width d1 of the first rear through-vias 160A and the width d2 of the second rear through-vias 160B may be different from each other.

Referring to FIG. 2B, in the semiconductor package 10b according to an example embodiment, the plurality of rear through-vias 160 may have different widths. For example, the width d2 of the second rear through-vias 160B may be greater than the width d1 of the first rear through-vias 160A. According to an example embodiment, the width d2 of the second rear through-vias 160B may also be smaller than the width d1 of the first rear through-vias 160A.

Referring to FIG. 2C, in the semiconductor package 10c of an example embodiment, the barrier insulating layer 167 may be disposed only on the first rear through-vias 160A, and may not be disposed between the second rear through-vias 160B and the substrate 110. In this case, a first recess surface RB1 of the substrate 110 surrounding lower portions of the first rear through-vias 160A and a second recess surface RB2 of the substrate 110 surrounding lower portions of the second rear through-vias 160B may have different sizes. For example, the second recess surface RB2 may be located on a higher level than the first recess surface RB1, but an example embodiment thereof is not limited thereto.

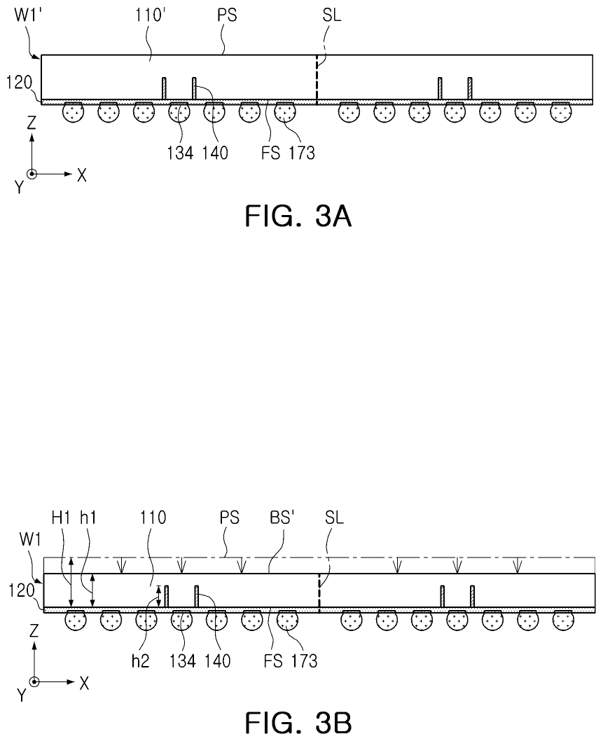

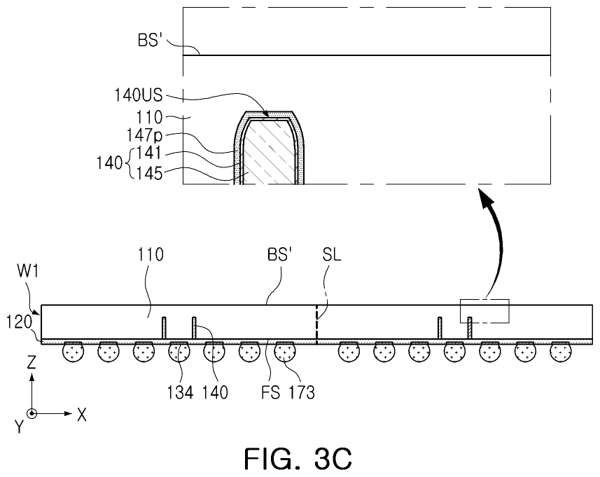

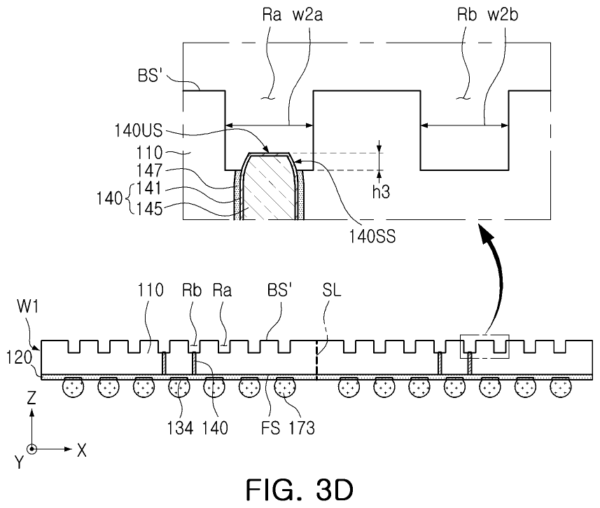

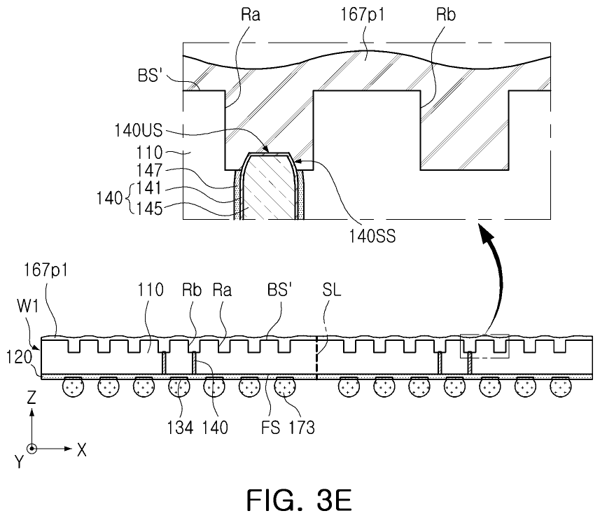

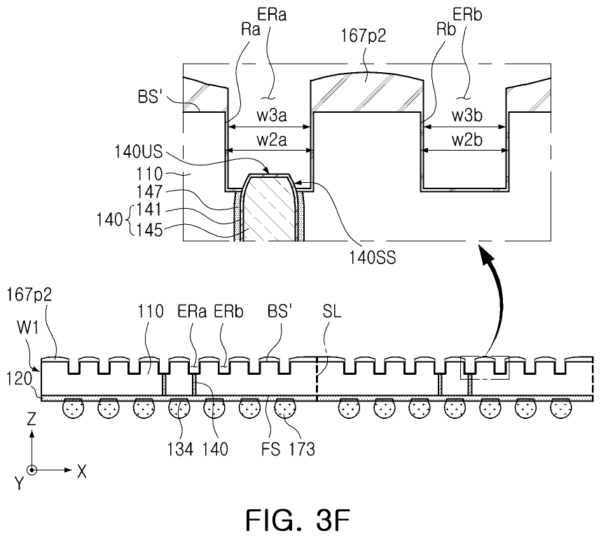

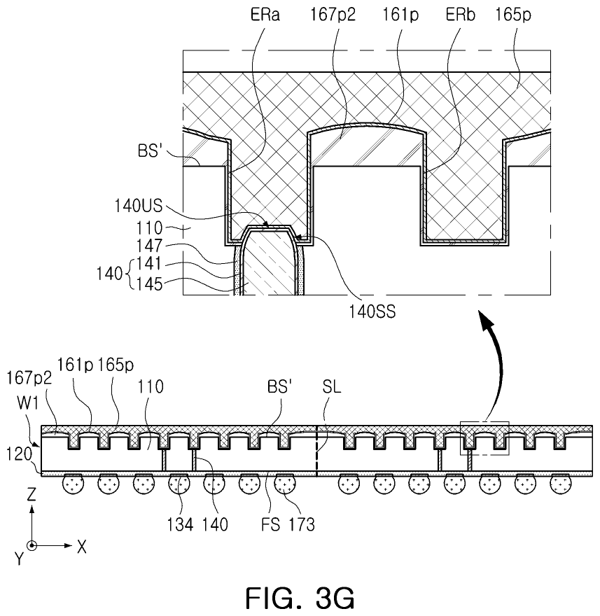

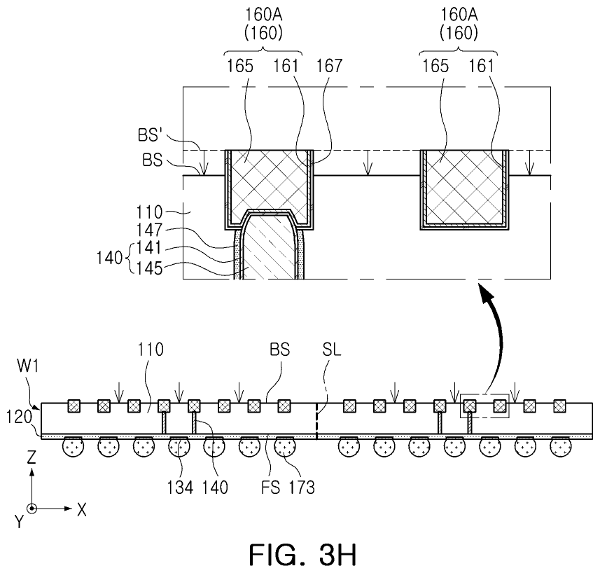

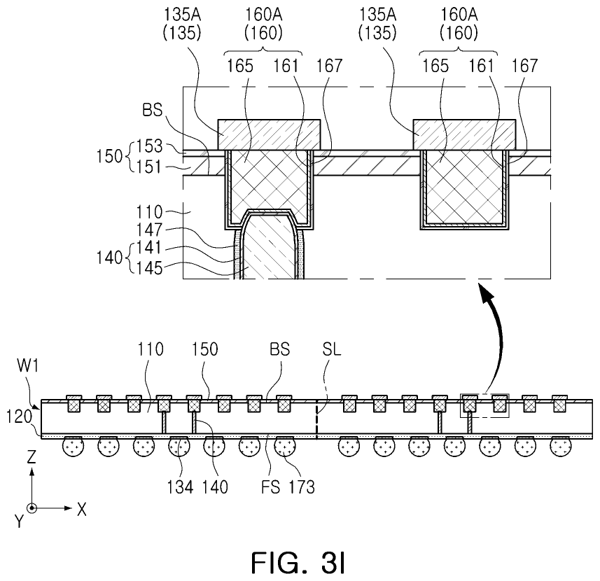

FIGS. 3A to 3I are cross-sectional views of major processes of a method of manufacturing a semiconductor package according to an example embodiment of the present inventive concept. FIGS. 3A to 3I show a manufacturing process of the first semiconductor chip 100A illustrated in FIG. 1A according to a process sequence.

Referring to FIG. 3A, a preliminary semiconductor wafer W1′ is prepared. The preliminary semiconductor wafer W1′ may be in a state in which a front circuit layer 120, front pads 134, and connection bumps 173, for the plurality of semiconductor chips are formed below the front surface FS of the preliminary substrate 110′. The preliminary semiconductor wafer W1′ may include a plurality of front through-vias 140 disposed in semiconductor chip regions separated by a scribe line SL. A carrier substrate (not shown) may be disposed below the preliminary semiconductor wafer W1′ to support and handle the preliminary semiconductor wafer W1′ when subsequent processes are performed. The preliminary semiconductor wafer W1′ may have an upper surface PS at a higher level than upper surfaces of the plurality of front through-vias 140.

Referring to FIGS. 3B and 3C, a semiconductor wafer W1 having a preliminary rear surface BS' positioned opposite to the front surface FS may be formed by performing a polishing process on an upper surface PS of the preliminary semiconductor wafer W1′. A semiconductor wafer W1 having a reduced thickness may be formed by partially removing an upper portion of the preliminary semiconductor wafer W1′ by a polishing process. For example, a thickness h1 of the substrate 110 after the polishing process may be smaller than a thickness H1 of the preliminary substrate 110′. However, the substrate 110 may have a thickness h1 at which the plurality of front through-vias 140 are not exposed to the preliminary rear surface BS′ formed by the polishing process. For example, the height or thickness h1 between the preliminary rear surface BS and the front surface FR of the substrate 110 may be greater than a height or thickness h2 of the plurality of front through-electrodes 140. In the polishing process, a chemical mechanical polishing (CMP) process, an etch-back process, or a combination thereof may be used. The plurality of front through-vias 140 may be covered by a preliminary side insulating film 147p. The preliminary side insulating film 147p may include, for example, a HARP oxide layer.

Referring to FIG. 3D, a plurality of recess portions Ra and Rb extending into the semiconductor wafer W1 may be formed by etching a portion of the semiconductor wafer W1 (or the substrate 110). A portion of the semiconductor wafer W1 may be removed by an etching process to form a plurality of recess portions Ra and Rb. In the etching process, for example, a reactive-ion etching (RIE) process using a photoresist (not shown), or the like, may be used. The plurality of recess portions Ra and Rb may be formed to have a depth so that upper ends of the plurality of front through-vias 140 protrude from bottom surfaces of the corresponding first recess portions Ra, respectively. Accordingly, the front through-vias 140 corresponding to the first recess portions Ra may have an upper surface 140US and a side surface 140SS protruding from the bottom surfaces of the first recess portions Ra. In addition, as a portion of the preliminary side insulating film 147p is removed by an etching process, the upper surface 140US and the side surface 140SS of the front through-vias 140 may be exposed from the side insulating film 147. The front through-vias 140 may protrude from the bottom surfaces of the first recess portions Ra to a predetermined height h3. The front through-vias 140 may protrude as far as necessary to secure connection reliability of rear through-vias to be described later. According to an example embodiment, only the upper surfaces 140US of the front through-vias 140 may be exposed to the bottom surfaces of the first recess portions Ra, and the side surfaces 140SS thereof may not be exposed.

The plurality of recess portions Ra and Rb may be formed to have widths w2a and w2b, greater than the widths of the plurality of front through-vias 140. The width w2a of the first recess portion Ra may be substantially the same as the width w2b of the second recess portion Rb, but may be different from each other according to example embodiments.

Referring to FIG. 3E, a first preliminary barrier insulating layer 167p1 filling the plurality of recess portions Ra and Rb may be formed. The first preliminary barrier insulating layer 167p1 may include, for example, silicon oxide (SiO), and an HDP oxide layer. The first preliminary barrier insulating layer 167p1 may cover a preliminary rear surface BS′, and may be formed to fill insides of the plurality of recess portions Ra and Rb. Accordingly, the first preliminary barrier insulating layer 167p1 may be in contact with an inner surface and a bottom surface of each of the plurality of recess portions Ra and Rb.

Referring to FIG. 3F, a portion of the first preliminary barrier insulating layer 167p1 may be etched to form a second preliminary barrier insulating layer 167p2 extending in the inner surface and a bottom surface of each of the plurality of recess portions Ra and Rb. A portion of the first preliminary barrier insulating layer 167p1 may be removed by the etching process to form a plurality of etched regions ERa and ERb. In the etching process, for example, a RIE process using a photoresist (not shown) may be used.

The plurality of etched regions ERa and ERb may be formed so that at least a portion of the second preliminary barrier insulating layer 167p2 conformally extends along the inner surface and the bottom surface of each of the plurality of recess portions Ra and Rb. For example, a width w3a of the first etched region ERa may be smaller than the width w2a of the first recess portion Ra, and a width w3b of the second etched region ERb may be smaller than the width w3b of the second recess portion Ra. Accordingly, at least a portion of the side surfaces 140SS of the front through-vias 140 exposed from the side insulating film 147 may contact the second preliminary barrier insulating layer 167p2.

Referring to FIG. 3G, a preliminary barrier layer 161p and a preliminary plug layer 165p may be formed in the etched regions ERa and ERb of the second preliminary barrier insulating layer 167p2. The preliminary barrier layer 161p may be conformally formed along a surface of the second preliminary barrier insulating layer 167p2. The preliminary plug layer 165p may be formed on the preliminary barrier layer 161p, and may fill insides of the plurality of etched regions ERa and ERb. The preliminary barrier layer 161p and the preliminary plug layer 165p may be formed by using a plating process, a PVD process, or a CVD process. For example, the preliminary barrier layer 161p may include titanium (Ti) or titanium nitride (TiN), and the preliminary plug layer 165p may include copper (Cu). A seed layer (not shown) including the same material as the preliminary plug layer 165p may be disposed between the preliminary barrier layer 161p and the preliminary plug layer 165p.

Referring to FIG. 3H, the preliminary plug layer 165p, the preliminary barrier layer 161p, and the second preliminary barrier insulating layer 167p2 may be polished to form a second via plug 165, a second surface barrier layer 161, and a barrier insulating layer 161. In addition, a rear surface BS of the substrate 110 may be formed by applying an etch-back process. A portion of each of the preliminary plug layer 165p and the preliminary barrier layer 161p may be removed by a polishing process, and a plurality of rear through-vias 160 including a second via plug 165 and a second surface barrier layer 161 may be formed. In addition, a barrier insulating layer 167 may be formed to surround the side and lower surfaces thereof. The polishing process may be performed using, for example, a CMP process.

Referring to FIG. 3I, a rear surface protective layer 150 may be formed on a rear surface BS of the substrate 110. The rear protective layer 150 includes, for example, silicon oxide, and may be formed using a PVD or CVD process. According to an example embodiment, the rear protective layer 150 may include a first protective layer 151 including silicon oxide and a second protective layer 153 including silicon nitride. Thereafter, a plurality of rear surface pads 135 may be formed on a plurality of rear surface through-vias 160. The plurality of rear through-vias 160 may penetrate through the rear protective layer 150 to provide a heat dissipation path connecting the substrate 110 and the plurality of front through-vias 140 and the plurality of rear pads 135. Thereafter, second semiconductor chips (‘100B’ in FIG. 1A) may be mounted on the semiconductor wafer W1 using a thermal-compression bonding process.

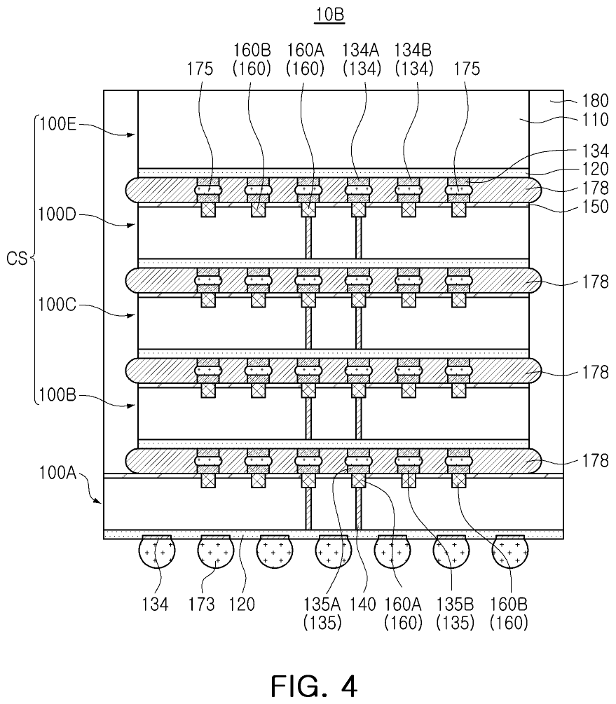

FIG. 4 is a cross-sectional view illustrating a semiconductor package 10B according to an example embodiment of the present inventive concept.

Referring to FIG. 4, the semiconductor package 10B of an example embodiment has the same or similar features as those described with reference to FIGS. 1A to 3I, except for including a chip structure CS and a molding member 180 disposed on the first semiconductor chip 100A, overlapping descriptions thereof will be omitted.

The chip structure CS may include a plurality of semiconductor chips, for example, a second semiconductor chip 100B, a third semiconductor chip 100C, a fourth semiconductor chip 100D, and a fifth semiconductor chip 100E. Bump structures 175 and adhesive layers 178 may be disposed between each of the first to fifth semiconductor chips 100A, 100B, 100C, 100D, and 100E. The fifth semiconductor chip 100E disposed at the top among the plurality of semiconductor chips may not include the front through-vias 140 and the rear through-vias 160, and may have a relatively thick thickness. According to an example embodiment, the chip structure CS may include more or less semiconductor chips than are shown in the drawings. For example, the chip structure CS may include 3 or less or 5 or more semiconductor chips. According to an example embodiment, a heat dissipation structure may be disposed above the chip structure CS. The heat dissipation structure (not shown) may include a material having excellent thermal conductivity, for example, aluminum (Al), gold (Au), silver (Ag), copper (Cu), iron (Fe), graphite, graphene, and the like.

For example, the first semiconductor chip 100A may be a buffer chip or a control chip including a plurality of logic devices and/or memory devices. The first semiconductor chip 100A may transmit a signal from the second to fifth semiconductor chips 100B, 100C, 100D, and 100E stacked thereon externally, and may transmit a signal and power from the outside to the second to fifth semiconductor chips 100B, 100C, 100D, and 100E. The second to fifth semiconductor chips 100B, 100C, 100D, and 100E may be memory chips including volatile memory devices such as DRAM and SRAM or non-volatile memory devices such as PRAM, MRAM, FeRAM, or RRAM. In this case, the semiconductor package 10B of the present embodiment may be used for a high bandwidth memory (HBM) product, an electronic data processing (EDP) product, or the like.

The molding member 180 may be disposed on the first semiconductor chip 100A, and may seal at least a portion of each of the second to fifth semiconductor chips 100B, 100C, 100D, and 100E. The molding member 180 may be formed to expose an upper surface of the fifth semiconductor chip 100E disposed at the top. However, according to example embodiments, the molding member 180 may also be formed to cover the upper surface of the fifth semiconductor chip 100E. The molding member 180 may include, for example, an epoxy mold compound (EMC), but a material of the molding member 180 is not particularly limited.

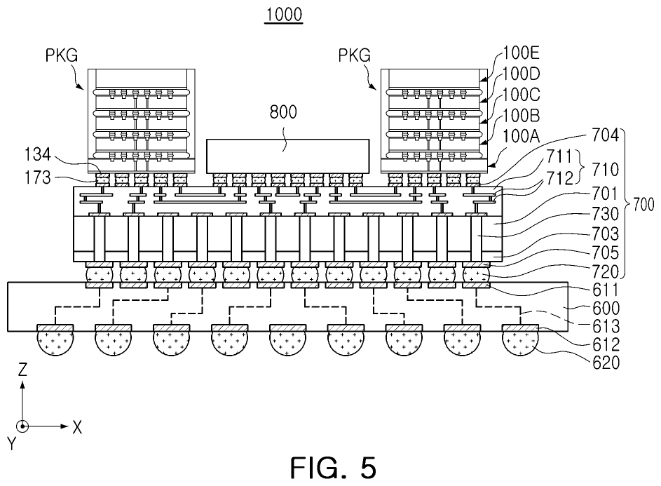

FIG. 5 is a cross-sectional view illustrating a semiconductor package 1000 according to an example embodiment.

Referring to FIG. 5, the semiconductor package 1000 according to an example embodiment may include a package substrate 600, an interposer substrate 700, and at least one package structure PKG. In addition, the semiconductor package 1000 may further include a logic chip or processor chip 800 disposed adjacent to the package structure PKG on the interposer substrate 700. The package structure PKG may have characteristics the same as or similar to those of semiconductor packages 10, 10a, 10b, 10c, and 10B described with reference to FIGS. 1A to 4.

The package substrate 600 is a support substrate on which the interposer substrate 700, the logic chip 800, and the package structure PKG are mounted, and may be a substrate for a substrate package including a printed circuit board PCB, a ceramic substrate, a glass substrate, a tape interconnection board, and the like. The package substrate 600 may include a lower pad 612, an upper pad 611, and an interconnection circuit 613 electrically connecting the lower pad 612 and the upper pad 611. A body of the package substrate 600 may include different materials depending on the type of substrate. For example, when the package substrate 600 is a printed circuit board, it may have a form in which interconnection layers are additional stacked on one or both surfaces of a body copper-clad laminate or a copper-clad laminate. The lower and upper pads 612 and 611 and the redistribution circuit 613 may form an electrical path connecting lower and upper surfaces of the package substrate 600. An external connection bump 620 connected to the lower pad 612 may be disposed on the lower surface of the package substrate 600. The external connection bump 620 may include, for example, a solder ball.

The interposer substrate 700 may include a substrate 701, a lower protective layer 703, a lower pad 705, an interconnection structure 710, conductive bumps 720, and through-vias 730. The package structure PKG and a processor chip 800 may be stacked on the package substrate 600 via the interposer substrate 700. The interposer substrate 700 may electrically connect the package structure PKG and the processor chip 800 to each other.

The substrate 701 may be formed of, for example, any one of silicon, organic, plastic, and glass substrates. When the substrate 701 is a silicon substrate, the interposer substrate 700 may be referred to as a silicon interposer. Unlike as illustrated in the drawings, when the substrate 701 is an organic substrate, the interposer substrate 700 may be referred to as a panel interposer.

A lower protective layer 703 may be disposed on a lower surface of the substrate 701, and a lower pad 705 may be disposed on the lower protective layer 703. The lower pad 705 may be connected to the through-vias 730. The package structure PKG and the processor chip 800 may be electrically connected to the package substrate 600 through the conductive bumps 720 disposed on the lower pad 705.

The interconnection structure 710 may be disposed on an upper surface of the substrate 701, and may include an interlayer insulating layer 711 and a monolayer or multilayer interconnection structure 712. When the interconnection structure 710 is formed of a multilayer interconnection structure, interconnection patterns of different layers may be connected to each other through contact vias. An upper pad 704 connected to the interconnection structure 712 may be disposed on the interconnection structure 710. The package structure PKG and the processor chip 800 may be connected to the upper pad 704 through the connection bump 139.

The through-via 730 may extend from the upper surface to the lower surface of the substrate 701 to pass through the substrate 701. In addition, the through-via 730 may extend into the interconnection structure 710, and also be electrically connected to interconnections of the interconnection structure 710. When the substrate 701 is silicon, the through-vias 730 may be referred to as TSVs. According to an example embodiment, the interposer substrate 700 may include only interconnection structures therein, and may not include through-vias.

The interposer substrate 700 may be used for the purpose of converting or transmitting an input electrical signal between the package substrate 600 and the package structure PKG or the processor chip 800. Accordingly, the interposer substrate 700 may not include devices such as active devices, passive devices, or the like. According to an example embodiment, the interconnection structure 710 may be disposed below the through-vias 730.

The conductive bumps 720 may be disposed on a lower surface of the interposer substrate 700 and electrically connected to interconnections of the interconnection structure 710. The interposer substrate 700 may be mounted on the package substrate 600 through the conductive bumps 720. The conductive bumps 720 may be connected to a lower pad 705 through the interconnections of the interconnection structure 710 and the through-vias 730. For example, a portion of the lower pads 705 used for power or ground are integrated and connected to the conductive bumps 720, so that the number of lower pads 705 may be greater than the number of conductive bumps 720.

The logic chip or processor chip 800 may include, for example, a central processor (CPU), a graphics processor (GPU), a field programmable gate array (FPGA), a digital signal processor (DSP), a cryptographic processor, a microprocessor, and a microcontroller, an analog-to-digital converter, an application specific integrated circuits (ASIC), and the like.

As set forth above, according to example embodiments, a semiconductor package having improved heat dissipation characteristics may be provided by introducing rear through-vias to a backside of a semiconductor chip.

The various advantages and effects of the present inventive concept are not limited to the above description, and may be more easily understood in the course of describing the specific embodiments of the present inventive concept. While example embodiments have been shown and described above, it will be apparent to those skilled in the art that modifications and variations could be made without departing from the scope of the present inventive concept, as defined by the appended claims.

While example embodiments have been shown and described above, it will be apparent to those skilled in the art that modifications and variations could be made without departing from the scope of the present inventive concept as defined by the appended claims.

What is claimed is:

1. A semiconductor package, comprising:
a first semiconductor chip comprising a substrate having a front surface and an opposite rear surface, a rear protective layer on the rear surface of the substrate, a plurality of first rear through-vias penetrating through the rear protective layer and extending into the substrate, a plurality of second rear through-vias penetrating through the rear protective layer and extending into the substrate, a plurality of front through-vias extending from the front surface of the substrate and connected to the plurality of first rear through-vias, and a plurality of rear pads on the rear protective layer, wherein the plurality of rear pads are connected to the plurality of first and second rear through-vias;
a second semiconductor chip on the first semiconductor chip, the second semiconductor chip comprising a plurality of front pads electrically connected to the plurality of rear pads;
a plurality of bump structures between the plurality of rear pads of the first semiconductor chip and the plurality of front pads of the second semiconductor chip; and
an adhesive layer surrounding the plurality of bump structures between the first semiconductor chip and the second semiconductor chip,
wherein each of the plurality of first and second rear through-vias has a width greater than a width of each of the plurality of front through-vias.

2. The semiconductor package of claim 1, wherein the first semiconductor chip comprises a center region and a peripheral region around the center region,
wherein the plurality of first rear through-vias are in the center region and the plurality of second rear through-vias are in the peripheral region.

3. The semiconductor package of claim 2, wherein the plurality of second rear through-vias are electrically insulated from the plurality of front through-vias.

4. The semiconductor package of claim 2, wherein the width of each of the plurality of second rear through-vias is different from the width of each of the plurality of first rear through-vias.

5. The semiconductor package of claim 4, wherein the width of each of the plurality of second rear through-vias is greater than the width of each of the plurality of first rear through-vias.

6. The semiconductor package of claim 1, wherein the first semiconductor chip further comprises a barrier insulating layer extending between at least a portion of the plurality of first and second rear through-vias and the substrate.

7. The semiconductor package of claim 6, wherein the barrier insulating layer comprises at least one of silicon oxide and silicon nitride.

8. The semiconductor package of claim 6, wherein the barrier insulating layer is only between the plurality of first rear through-vias and the substrate.

9. The semiconductor package of claim 1, wherein the width of each of the plurality of first and second rear through-vias is in a range of about 5 μm to about 15 μm, and
wherein the width of each of the plurality of front through-vias is in a range of about 2 μm to about 8 μm.

10. The semiconductor package of claim 1, wherein each of the plurality of first and second rear through-vias has a height smaller than a height of each of the plurality of front through-vias.

11. The semiconductor package of claim 10, wherein the height of each of the plurality of first and second rear through-vias is in a range of about 2 μm to about 10 μm.

12. The semiconductor package of claim 1, wherein the rear protective layer comprises at least one of silicon oxide and silicon nitride.

13. The semiconductor package of claim 1, wherein the substrate comprises at least one of a silicon and germanium.

14. A semiconductor package, comprising:
a plurality of semiconductor chips stacked in a first direction;
a plurality of bump structures between and electrically connecting adjacent ones of the plurality of semiconductor chips; and
at least one adhesive layer surrounding the plurality of bump structures,
wherein at least one of the plurality of semiconductor chips comprises:
a substrate having a front surface and an opposite rear surface;
a rear protective layer on the rear surface of the substrate;
a plurality of rear pads on the rear protective layer;
a plurality of rear through-vias penetrating through the rear protective layer and connected to the plurality of rear pads;
a front circuit layer on the front surface of the substrate;
a plurality of front pads on the front circuit layer, and
a plurality of front through-vias extending from the front surface of the substrate to at least some of the plurality of rear through-vias, and electrically connected to at least some of the plurality of front pads.

15. The semiconductor package of claim 14, wherein the plurality of rear pads and the plurality of front pads that are adjacent to each other in the first direction are electrically connected to each other by the plurality of bump structures.

16. The semiconductor package of claim 14, wherein, in the first direction, a height of each of the plurality of rear through-vias is smaller than a height of each of the plurality of front through-vias.

17. The semiconductor package of claim 14, wherein in a second direction that is transverse to the first direction, a width of each of the plurality of rear through-vias is greater than a width of each of the plurality of front through-vias.

18. The semiconductor package of claim 14, further comprising:
a molding member encapsulating at least a portion of each of the plurality of semiconductor chips.

19. A semiconductor package, comprising:
a first semiconductor chip comprising a substrate having a front surface and an opposite rear surface, a rear protective layer on the rear surface of the substrate, a plurality of rear through-vias penetrating through the rear protective layer and extending into the substrate, a plurality of front through-vias extending from the front surface of the substrate and connected to the plurality of rear through-vias, and a plurality of rear pads on the rear protective layer and connected to the plurality of rear through-vias;
a second semiconductor chip on the first semiconductor chip, the second semiconductor chip comprising a plurality of front pads electrically connected to the plurality of rear pads;
a plurality of bump structures between the plurality of rear pads of the first semiconductor chip and the plurality of front pads of the second semiconductor chip;
an adhesive layer surrounding the plurality of bump structures between the first semiconductor chip and the second semiconductor chip,
wherein the plurality of rear through-vias comprise a plurality of first rear through-vias electrically connected to the plurality of front through-vias, and a plurality of second rear through-vias electrically insulated from the plurality of front through-vias.

20. The semiconductor package of claim 19, wherein a lower surface of each of the plurality of first rear through-vias comprises a recess portion in contact with an upper surface of a respective one of the plurality of front through-vias.
